(19) United States
(12) Patent Application Publication
(10) Pub. No.: US 2014/0252299 A1
(43) Pub. Date: Sep. 11, 2014

(54) SEMICONDUCTOR DEVICE AND METHOD FOR FABRICATING THE SAME, AND MICRO PROCESSOR, PROCESSOR, SYSTEM, DATA STORAGE SYSTEM AND MEMORY SYSTEM INCLUDING THE SEMICONDUCTOR DEVICE

(71) Applicant: SK HYNIX INC., Icheon (KR)

(72) Inventors: Hye-Jung CHOI, Icheon (KR); Jun-Kyo SUH, Icheon (KR)

(21) Appl. No.: 13/924,428

(22) Filed: Jun. 21, 2013

(30) Foreign Application Priority Data
Mar. 7, 2013 (KR) 10-2013-0024357

(51) Int. Cl. H01L 45/00

(52) U.S. Cl. CPC H01L 45/1253
USPC 257/4

(57) ABSTRACT

A semiconductor device includes a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

### CROSS-REFERENCE TO RELATED APPLICATION

The present application claims priority of Korean Patent Application No. 10-2013-0024357, filed on Mar. 7, 2013, which is incorporated herein by reference in its entirety.

### BACKGROUND

1. Field

Exemplary embodiments relate to a semiconductor device and a method for fabricating the same, and more particularly, to a semiconductor device which has a cross point structure, and a method for fabricating the same.

2. Description of the Related Art

Recently, as a trend of electronic appliances is heading toward miniaturization, low power consumption, high performance, multi-functionality, and so on, semiconductor devices capable of storing information in various electronic appliances such as a computer, a portable communication device, and the like have been demanded in the art, and research has been conducted for the semiconductor devices. Such semiconductor devices include semiconductor devices which can store data using a resistance variable layer to be switched between different resistant states according to an applied voltage or current. For example, data ‘0’ or ‘1’ may be stored according to whether the resistance variable layer is in a high resistant state or a low resistant state. Currently, various semiconductor devices such as a resistive random access memory (ReRAM), a phase change random access memory (PCRAM), a ferroelectric random access memory (FRAM), a magnetic random access memory (MRAM), an E-fuse, etc. have been developed.

These semiconductor devices may be embodied in a cross point structure to increase the degree of integration. Hereinbelow, detailed descriptions will be given with reference to FIG. 1.

FIG. 1 is a perspective view illustrating a conventional semiconductor device, specifically, a conventional semiconductor device with a cross point structure.

Referring to FIG. 1, a conventional semiconductor device includes a plurality of first conductive lines 11 which extend in a first direction, a plurality of second conductive lines 13 which extend in a second direction crossing the first direction, and resistance variable elements 12 which are interposed between the first conductive lines 11 and the second conductive lines 13 and are disposed at respective cross points of the first conductive lines 11 and the second conductive lines 13.

Since a resistance variable element 12 disposed at the cross point of a selected first conductive line 11 and a selected second conductive line 13 may be controlled by applying voltages or current to the selected first conductive line 11 and the selected second conductive line 13, each unit memory cell is disposed at each cross point of the first and second conductive lines 11 and 13.

Each resistance variable element 12 is formed to have an island shape to prevent disturbance between cells.

However, when fabricating the above-described semiconductor device, limitations exist in decreasing a unit size of the resistance variable element 12 due to a limit in a photolithographic process. In this regard, recently, as a design rule of a semiconductor device decreases, it is substantially impossible to form the resistance variable element 12 in such a small size satisfying a given design rule, through one masking and etching process.

While a spacer patterning technology has been disclosed in the art as a method for forming fine patterns with a size smaller than the limit allowed in a given photolithographic process, since the spacer patterning technology is a technology used in forming line/space type patterns, the spacer patterning technology is not appropriate to forming the resistance variable elements 12 with island shapes. Thus, in order to apply the spacer patterning technology to form the resistance variable elements 12 with the island shape, the spacer patterning process should be performed twice, rather than once. As a consequence, processing is complicated, and a processing time and production costs increase.

### SUMMARY

Various embodiments are directed to a semiconductor device in which processing is simplified and which can reduce disturbance between cells, and a method for fabricating the same.

In an embodiment, a semiconductor device may include: a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

In an embodiment, a method for fabricating a semiconductor device may include: forming first conductive lines which extend in a first direction; forming resistance variable lines which extend in a third direction crossing the first direction and provided over the first conductive lines; and forming second conductive lines which extend in a second direction crossing the first and third directions and provided over the resistance variable lines.

In an embodiment, a method for fabricating a semiconductor device may include: forming first conductive lines which extend in a first direction; forming stack lines which extend in a third direction crossing the first direction, wherein the stack lines include resistance variable lines and third conductive lines and are formed over the first conductive lines; forming second conductive lines which extend in a second direction crossing the first and third directions, over the stack lines; and patterning the third conductive lines to remove portions exposed by the second conductive lines.

In an embodiment, a microprocessor may include: a control unit configured to receive a signal including an external command, and to perform extraction, decoding, and controlling of input and output of the external command; an operation unit configured to perform an operation in response to a signal of the control unit; and a memory unit configured to store any of (i) data for performing the operation, (ii) data corresponding to a result of performing the operation, and (iii) an address of data for which the operation is performed, wherein the memory unit comprises: a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

In an embodiment, a processor may include: a core unit configured to perform, in response to an external command, an operation corresponding to the external command, by using data; a cache memory unit configured to store any of (i) data for performing the operation, (ii) data corresponding to a result of performing the operation, and (iii) an address of data for which the operation is performed; and a bus interface connected between the core unit and the cache memory unit, and configured to transmit data between the core unit and the cache memory unit, wherein the cache memory unit comprises: a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

In an embodiment, a system may include: a processor configured to decode a command inputted from outside and control an operation for information according to a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between (i) at least one of the processor, the auxiliary memory device and the main memory device and (ii) the outside, wherein at least one of the auxiliary memory device and the main memory device comprises: a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

In an embodiment, a data storage system may include: a storage device configured to store data and preserve stored data regardless of power supply; a controller configured to control input and output of data to and from the storage device in response to an external command received from outside; a temporary storage device configured to temporarily store data exchanged between the storage device and the outside; and an interface configured to perform communication between (i) at least one of the storage device, the controller, and the temporary storage device and (ii) the outside, wherein at least one of the storage device and the temporary storage device comprises: a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

In an embodiment, a memory system may include: a memory configured to store data and preserve stored data regardless of power supply; a memory controller configured to control input and output of data to and from the memory in response to an external command received from outside; a buffer memory configured to buffer data exchanged between the memory and the outside; and an interface configured to perform communication between (i) at least one of the memory, the memory controller, and the buffer memory and (ii) the outside, wherein at least one of the memory and the buffer memory comprises: a plurality of first conductive lines extending in a first direction; a plurality of second conductive lines extending in a second direction crossing the first direction; and a plurality of resistance variable lines interposed between the first and the second conductive lines and extending in a third direction crossing the first and the second directions.

### BRIEF DESCRIPTION OF THE DRAWINGS

FIG. 1 is a perspective view illustrating a conventional semiconductor device.

FIGS. 2A and 2B are a perspective view and a plan view illustrating a semiconductor device in accordance with an embodiment.

FIGS. 3A to 3C are cross-sectional views explaining a method for fabricating the semiconductor device in accordance with the embodiment.

FIGS. 4A to 4C are cross-sectional views explaining a spacer patterning technology for forming lines of the semiconductor device in accordance with an embodiment.

FIGS. 5A and 5B are a perspective view and a plan view illustrating a semiconductor device for comparison with the semiconductor device of FIGS. 2A and 2B.

FIGS. 6A to 6D are cross-sectional views and a plan view explaining a semiconductor device in accordance with another embodiment and a method for fabricating the same.

FIG. 7 is a perspective view illustrating a semiconductor device in accordance with still another embodiment.

FIG. 8 is a configuration diagram of a microprocessor in accordance with an embodiment.

FIG. 9 is a configuration diagram of a processor in accordance with an embodiment.

FIG. 10 is a configuration diagram of a system in accordance with an embodiment.

FIG. 11 is a configuration diagram of a data storage system in accordance with an embodiment.

FIG. 12 is a configuration diagram of a memory system in accordance with an embodiment.

### DETAILED DESCRIPTION

Various embodiments will be described below in more detail with reference to the accompanying drawings. Embodiments may, however, be present in different forms and should not be construed as limited to those set forth herein. Throughout the disclosure, like reference numerals refer to like parts throughout the various figures and embodiments of the present invention.

The drawings are not necessarily correct in scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

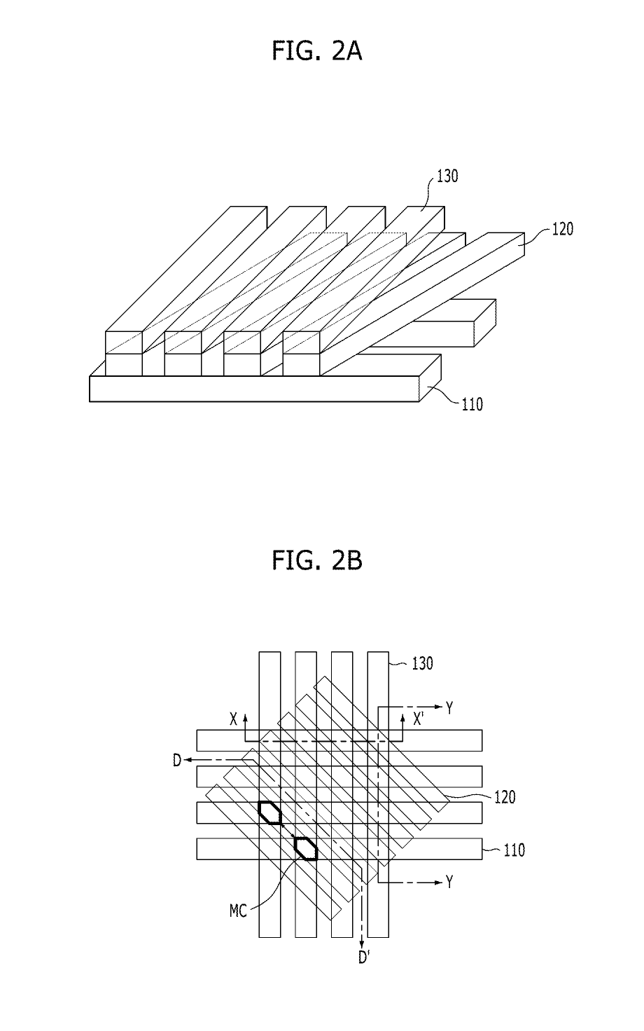

FIGS. 2A and 2B are respectively a perspective view and a plan view illustrating a semiconductor device in accordance with an embodiment.

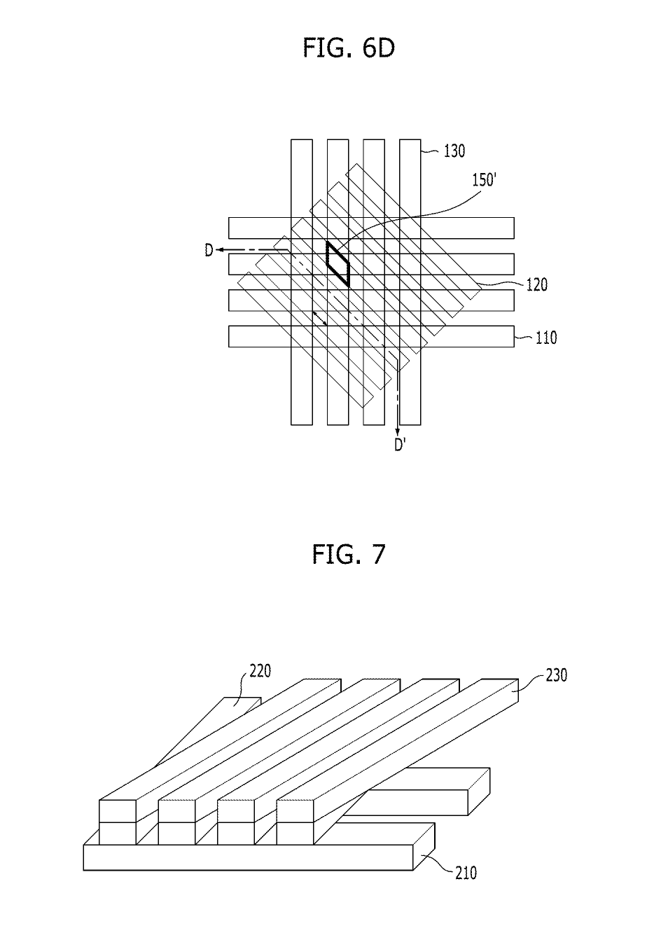

Referring to FIGS. 2A and 2B, a semiconductor device in accordance with an embodiment includes a plurality of first conductive lines 110 which extend in a first direction (see the direction of the line X-X′ of FIG. 2B), a plurality of second conductive lines 130 which extend in a second direction (see the direction of the line Y-Y′ of FIG. 2B) crossing the first direction, and a plurality of resistance variable lines 120 which are interposed between the first conductive lines 110 and the second conductive lines 130 and extend in a third direction (see the direction of the line D-D′ of FIG. 2B) crossing the first and second directions. In the present embodiment, the first conductive lines 110 and the second conductive lines 130 may form an approximately right angle, and the resistance variable lines 120 may be disposed obliquely with respect to the first conductive lines 110 and the second conductive lines 130. That is to say, angles which are formed between the third direction and the first and second directions may be between 0° and 90°, excluding 0°. However, embodiments are not limited to such, and the first direction, the second direction and the third direction may form various angles so long as they cross with one another. This is exemplarily shown in FIG. 7, and detailed descriptions thereof will be given in the corresponding part.

The first conductive lines 110 and the second conductive lines 130 apply voltages or current to the resistance variable lines 120 interposed therebetween, and may include a conductive substance, for example, platinum (Pt), tungsten (W), aluminum (Al), copper (Cu) or tantalum (Ta), or a metal nitride such as a titanium nitride (Tin) or a tantalum nitride (TaN).

The resistance variable lines 120 exhibit a resistance variable characteristic and may include a single layer or a multi-layer. For example, the resistance variable lines 120 may include a substance (or material) used in a ReRAM, a PCRAM, a MRAM, a FRAM, and so forth, for example, a chalcogenide-based compound, a transition metal compound, a ferroelectric material, a ferromagnetic material, etc. However, the embodiment is not limited to such, and any material having have a resistance variable characteristic can be employed for the resistance variable lines 120 so that the resistance variable lines 120 are switched between different resistant states according to voltages or current applied to both ends thereof.

One first conductive line 110, one second conductive line 130 and the resistance variable line 120 interposed therebetween may form a unit memory cell. Memory cells are respectively formed at regions (see the reference symbol MC) where the first conductive lines 110, the second conductive lines 130, and the resistance variable lines 120 overlap with one another.

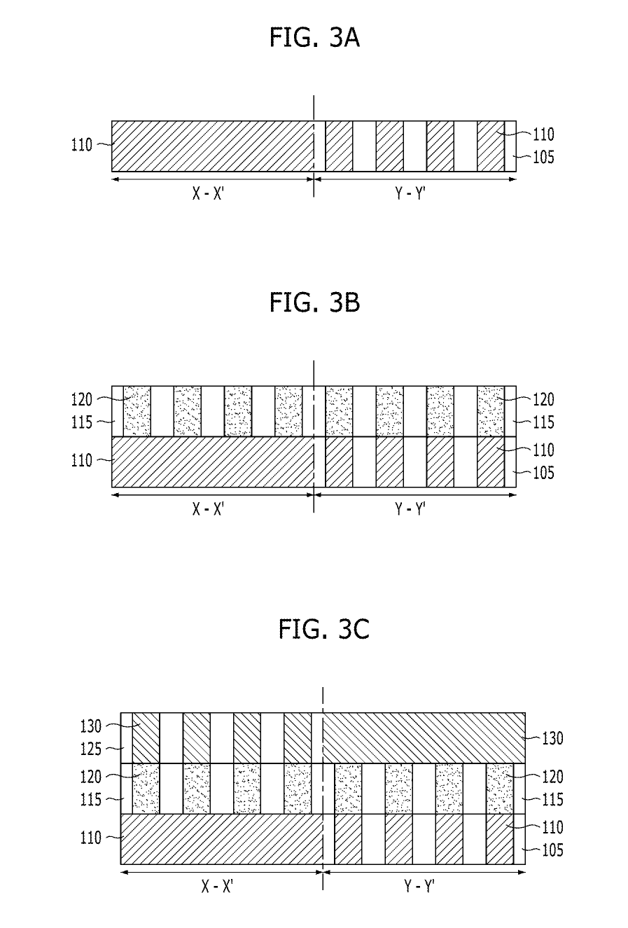

FIGS. 3A to 3C are cross-sectional views, specifically, taken along the lines X-X′ and Y-Y′ of FIG. 2B, explaining a method for fabricating the semiconductor device in accordance with the embodiment.

Referring to FIG. 3A, a plurality of first conductive lines 110 which extend in a first direction and a first dielectric layer 105 which fills spaces between the first conductive lines 110 are formed on a substrate (not shown) which may include predetermined desired underlying structures.

The first conductive lines 110 and the first dielectric layer 150 may be formed, for example, by steps of depositing a conductive substance on the substrate and forming the first conductive lines 110 by patterning the conductive substance and steps of depositing a dielectric substance to cover the first conductive lines 110 and forming the first dielectric layer 105 filled between the first conductive lines 110 by performing planarization until the first conductive lines 110 are exposed.

Referring to FIG. 3B, a plurality of resistance variable lines 120 which extend in a third direction, and a second dielectric layer 115 which fills spaces between the resistance variable lines 120, are formed on the first conductive lines 110 and the first dielectric layer 105.

The resistance variable lines 120 and the second dielectric layer 115 may be formed, for example, by steps of depositing a substance layer for formation of the resistance variable lines 120 on the first conductive lines 110 and the first dielectric layer 105 and forming the resistance variable lines 120 through patterning the substance layer and a step of forming the second dielectric layer 115 filled between the resistance variable lines 120.

Referring to FIG. 3C, a plurality of second conductive lines 130 which extend in a second direction and a third dielectric layer 125 which fills spaces between the second conductive lines 130 are formed on the resistance variable lines 120 and the second dielectric layer 115. Processes for forming the second conductive lines 130 and the third dielectric layer 125 may be performed in a manner similar to the processes for forming the first conductive lines 110 and the first dielectric layer 105.

The first to third dielectric layers 105, 115 and 125 may be formed using a dielectric substance such as an oxide or a nitride.

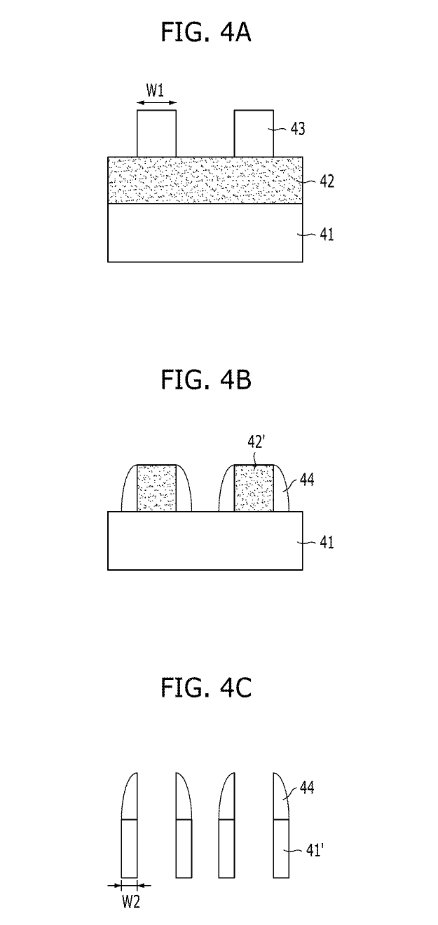

The first conductive lines 110, the resistance variable lines 120 or the second conductive lines 130 may be formed to have a width smaller than an exposure limit of a given exposure process, by using a spacer patterning technology. The spacer patterning technology will be described below in detail with reference to FIGS. 4A to 4C.

Referring to FIG. 4A, first, a layer-to-be-etched 41, which should be etched in a line type, is formed. In the present embodiment, the layer-to-be-etched 41 may be a conductive layer for forming the first conductive lines 110 or the second conductive lines 130 or a substance layer for forming the resistance variable lines 120.

After forming a sacrificial layer 42 on the layer-to-be-etched 41, mask patterns 43 are formed on the sacrificial layer 42 to cover spaces between regions where lines are to be formed. The mask patterns 43 may be formed through exposure and development processes and may have a width W1 equal to or larger than an exposure limit of a given exposure process.

Referring to FIG. 4B, after forming sacrificial layer patterns 42′ by etching the sacrificial layer 42 using the mask patterns 43 as etch barriers, the mask patterns 43 are removed.

Spacers 44 are formed on sidewalls of the sacrificial layer patterns 42′. The spacers 44 may be formed by depositing a substance layer for spacers on the entire surfaces of the sacrificial layer patterns 42′ and the layer-to-be-etched 41 and then performing blanket etching. By controlling a thickness of the substance layer for spacers, which is deposited, a horizontal width of the spacers 44 may be controlled. In other words, the horizontal width of the spacers 44 may be smaller than the exposure limit of the given exposure process.

Referring to FIG. 4C, after removing the sacrificial layer patterns 42′, by etching the layer-to-be-etched 41 using the spacers 44 as etch barriers, layer-to-be-etched patterns 41′ of line types are formed. The layer-to-be-etched patterns 41′ may have a width W2 equal to or smaller than the exposure limit. The width W2 may be substantially equal to the width of the spacers 44.

By employing the above-described spacer patterning technology shown in FIGS. 4A to 4C, it is possible to form the first conductive lines 110, the resistance variable lines 120 or the second conductive lines 130 with a width equal to or smaller than the exposure limit.

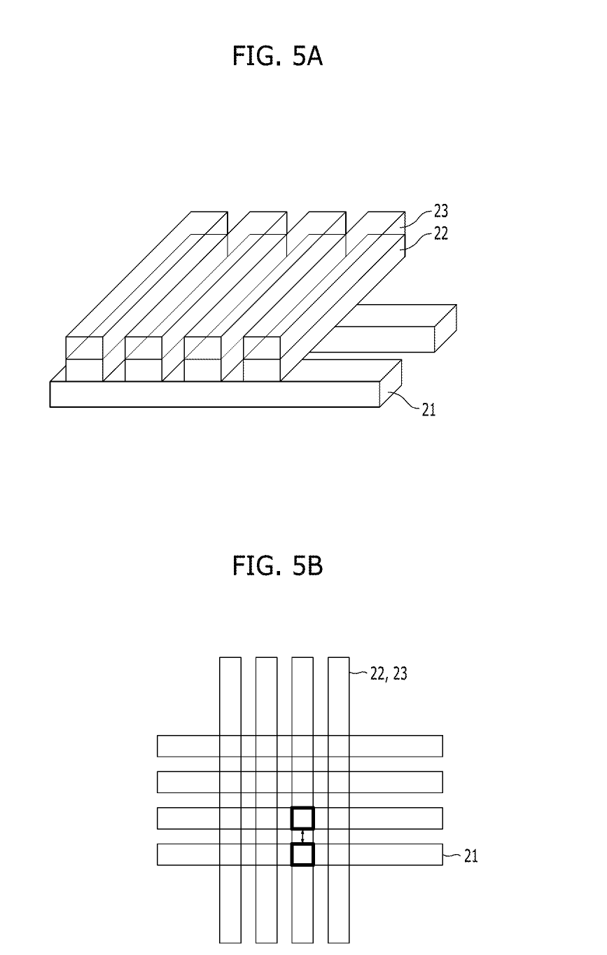

For comparison with the semiconductor device in accordance with the embodiment as mentioned above, a semiconductor device shown in FIGS. 5A and 5B will be additionally described below.

Referring to FIGS. 5A and 5B, in a semiconductor device of a comparative example, line type resistance variable lines 22 are interposed between first and second conductive lines 21 and 23 which cross each other, and the extending direction of the resistance variable lines 22 is the same as that of the second conductive lines 23. The resistance variable lines 22 may be formed when the second conductive lines 23 are formed.

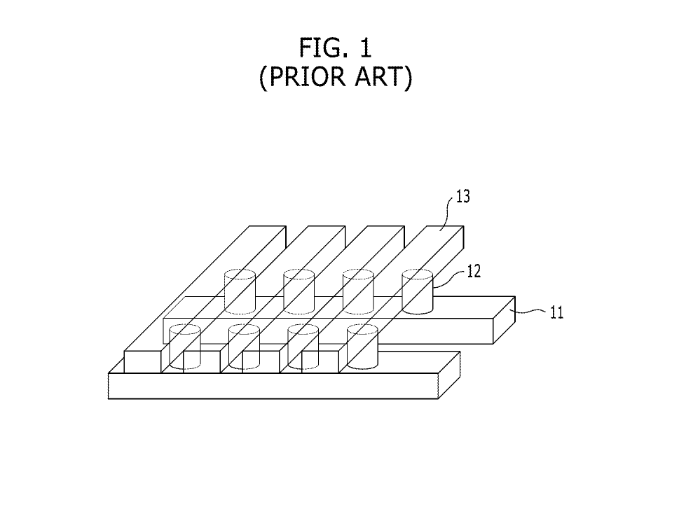

In the semiconductor device and the method for fabricating the same in accordance with the embodiments of the described above, the following possible benefits may be provided over the semiconductor devices and the methods for fabricating the same according to the conventional art (see FIG. 1) and the comparative example (see FIGS. 5A and 5B).

First, since the plurality of resistance variable lines 120 are formed into line/space patterns, simplification of processing is possible and a processing time and costs may be decreased, in comparison with the conventional art. In detail, in the case where the resistance variable lines 120 have a width equal to or smaller than an exposure limit, it is possible to form the resistance variable lines 120 by performing the spacer patterning process once, rather than multiple times. Conversely, in the case where resistance variable elements have an island shape as in the conventional art, in order to form the resistance variable elements with the same width as the resistance variable lines 120, a spacer patterning process should be performed at least twice, each along different directions.

In addition, because the resistance variable lines 120 are obliquely formed to have predetermined angles with respect to both the first conductive line 110 and the second conductive lines 130, a distance between neighboring memory cells may be increased. For instance, assume that, in the case of the comparative example, a distance (see [symbol] of FIG. 5B) between adjacent memory cells arranged along a given resistance variable line 22 is 1. Under the same condition except the structure of the resistance variable line 120, in the present embodiment, a distance (see [symbol] of FIG. 2B) between adjacent memory cells arranged along a given resistance variable line 120 becomes \sqrt{2}. Accordingly, interference between cells may be reduced.

Summarizing this, in the case of the present embodiment, due to the fact that the resistance variable lines have line shapes, potential advantages may be provided in fabricating a semiconductor device. Also, due to the fact that the resistance variable lines are arranged oblique with respective to upper and lower conductive lines 110, 130, the distance between neighboring memory cells which share the same resistance variable line may be increased, whereby interference between neighboring cells may be reduced.

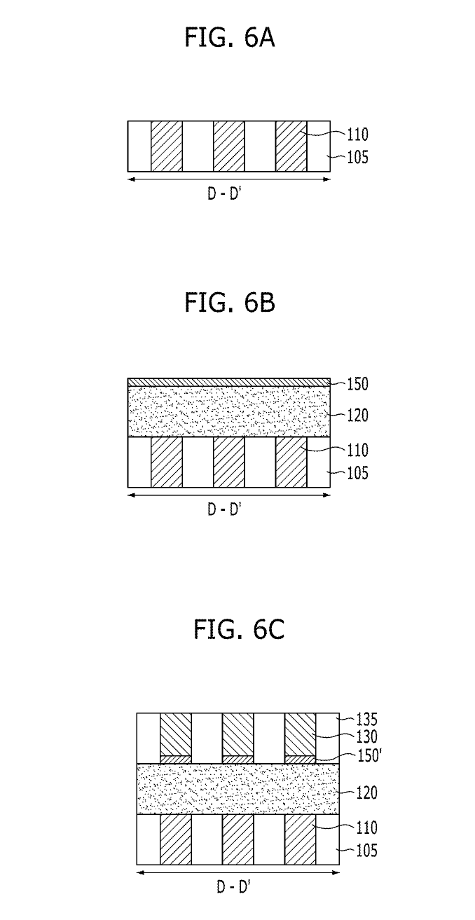

Meanwhile, in the semiconductor device of the aforementioned embodiment, a metal layer such as tungsten or a metal nitride layer such as a titanium nitride layer may be interposed between the resistance variable lines 120 and the overlying second conductive lines 130, as a protective layer for protecting interfaces of the resistance variable lines 120 and the second conductive lines 130. This will be described below in detail with reference to FIGS. 6A to 6D.

FIGS. 6A to 6D are cross-sectional views and a plan view explaining a semiconductor device in accordance with another embodiment and a method for fabricating the same. In particular, FIGS. 6C and 6D are a cross-sectional view and a plan view illustrating a semiconductor device, respectively, and FIGS. 6A and 6B are cross-sectional views illustrating intermediate processing steps for fabricating the semiconductor device of FIGS. 6C and 6D. FIGS. 6A to 6C are cross-sectional views taken along the line D-D′ of FIG. 6D.

Referring to FIG. 6A, a plurality of first conductive lines 110 which extend in a first direction and a first dielectric layer 105 which fills spaces between the first conductive lines 110 are formed on a substrate (not shown).

Referring to FIG. 6B, stack structures of resistance variable lines 120 and third conductive lines 150 which extend in a third direction are formed. The stack structures are formed by forming a resistance variable substance layer and a conductive substance layer for a protective layer sequentially on the first conductive lines 110 and the first dielectric layer 105, and then etching the resistance variable substance layer and the conductive substance layer into line patterns using a same mask. A dielectric substance (not shown in the figure) may be filled between the stack structures.

Referring to FIGS. 6C and 6D, after depositing a conductive layer for forming second conductive lines on the resultant of FIG. 6B, the conductive layer is etched using a mask, and further, the third conductive lines 150 are etched using the mask. As a result, second conductive lines 130 which extend in a second direction are formed, and the third conductive lines 150 are patterned into island types when viewed from the cross-section taken along the line D-D′. The reason why the third conductive lines 150 are patterned into the island types when viewed from the cross-section taken along the line D-D′ is to independently drive memory cells arranged along the direction to which the resistance variable lines 120 extend, that is, the third direction.

The etched third conductive lines 150 are hereinafter referred to as conductive patterns 150′. The conductive patterns 150′ may be interposed between the resistance variable lines 120 and the second conductive lines 130 and may protect the interfaces of the resistance variable lines 120 and the second conductive lines 130. As described above, the conductive patterns 150′ may include metal such as tungsten and/or metal nitride such as a titanium nitride. Since the conductive patterns 150′ are patterned when the resistance variable lines 120 and the second conductive lines 130 are formed, the conductive patterns 150′ may be formed at the cross points where the resistance variable lines 120 and the second conductive lines 130 overlap with each other.

FIG. 7 is a perspective view illustrating a semiconductor device in accordance with still another embodiment.

Referring to FIG. 7, the semiconductor device includes a plurality of first conductive lines 210 which extend in a first direction, a plurality of second conductive lines 230 which extend in a second direction crossing the first direction, and a plurality of resistance variable lines 220 which are interposed between the first conductive lines 210 and the second conductive lines 230 and extend in a third direction crossing both of the first and second directions. In the present embodiment, the first conductive lines 210 and the resistance variable lines 220 may form an approximately right angle, and the second conductive lines 230 may be arranged obliquely with respect to the first conductive lines 210 and the resistance variable lines 220.

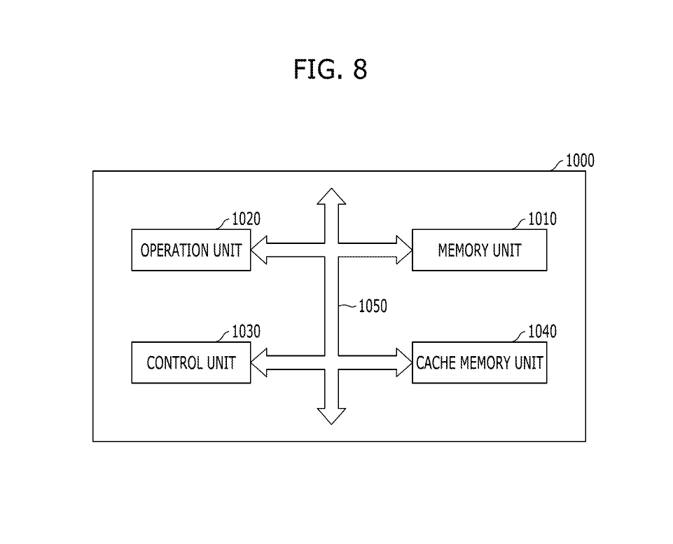

FIG. 8 is a configuration diagram of a microprocessor in accordance with an embodiment.

Referring to FIG. 8, a microprocessor 1000 may perform tasks for controlling and tuning a series of processes of receiving data from various external devices, processing the data, and outputting processing results to external devices. The microprocessor 1000 may include a memory unit 1010, an operation unit 1020 and a control unit 1030. The microprocessor 1000 may be various processing units such as a central processing unit (CPU), a graphic processing unit (GPU), a digital signal processor (DSP) and an application processor (AP).

The memory unit 1010 is a part which stores data in the microprocessor 1000, as a processor register or a register. The memory unit 1010 may include a data register, an address register and a floating point register. Besides, the memory unit 1010 may include various registers. The memory unit 1010 may perform the function of temporarily storing data for which operations are to be performed by the operation unit 1020, result data of performing the operations and an address where data for performing of the operations are stored.

The memory unit 1010 may include one of the above-described semiconductor devices in accordance with the embodiments. The memory unit 1010 including the semiconductor device in accordance with the aforementioned embodiment may include a plurality of first conductive lines extending in a first direction, a plurality of second conductive lines extending in a second direction crossing the first direction, and a plurality of resistance variable lines interposed between the first and second conductive lines and extending in a third direction crossing the first and second directions. Through this, a fabrication process of the memory unit 1010 may become simplified and the reliability of the memory unit 1010 may be improved. As a consequence, a fabrication process of the microprocessor 1000 may become easy and the reliability of the microprocessor 1000 may be improved.

The operation unit 1020 is a part which performs operations in the microprocessor 1000. The operation unit 1020 performs arithmetical operations or logical operations according to signals transmitted from the control unit 1030. The operation unit 1020 may include at least one arithmetic logic unit (ALU).

The control unit 1030 receives signals from the memory unit 1010, the operation unit 1020 and an external device of the microprocessor 1000, performs extraction, decoding and controlling upon input and output of commands, and executes processing represented by programs.

The microprocessor 1000 according to the present embodiment may additionally include a cache memory unit 1040 which can temporarily store data to be inputted from an external device or to be outputted to an external device. In this case, the cache memory unit 1040 may exchange data with the memory unit 1010, the operation unit 1020 and the control unit 1030 through a bus interface 1050.

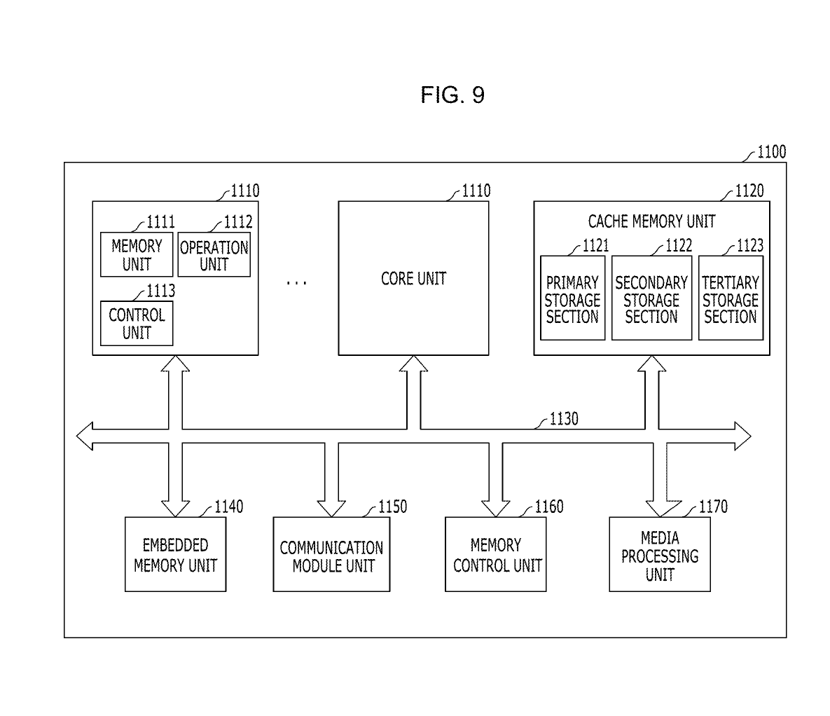

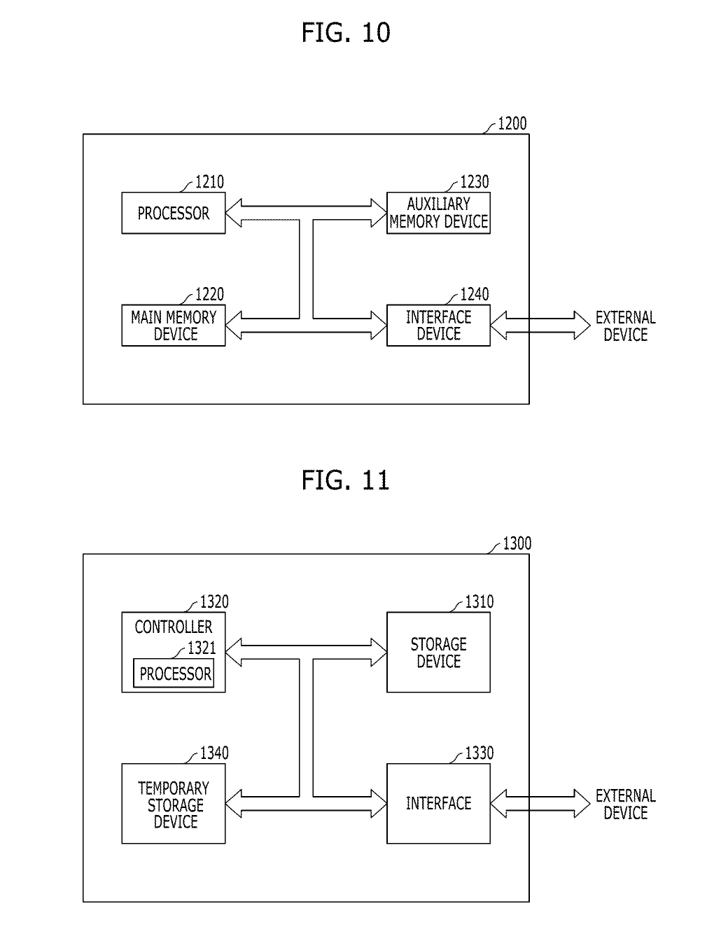

FIG. 9 is a configuration diagram of a processor in accordance with an embodiment.

Referring to FIG. 9, a processor 1100 may improve performance and realize multi-functionality by including various functions in addition to the function which is performed by a microprocessor such as controlling and tuning a series of processes of receiving data from various external devices, processing the data, and outputting processing results to external devices. The processor 1100 may include a core unit 1110, a cache memory unit 1120, and a bus interface 1130. The core unit 1110 of the present embodiment is a part which performs arithmetic logic operations for data inputted from an external device, and may include a memory unit 1111, an operation unit 1112 and a control unit 1113. The processor 1100 may be various system-on-chips (SoCs) such as a multi-core processor, a graphic processing unit (GPU) and an application processor (AP).

The memory unit 1111 is a part which stores data in the processor 1100, as a processor register or a register. The memory unit 1111 may include a data register, an address register and a floating point register. Besides, the memory unit 1111 may include various registers. The memory unit 1111 may perform the function of temporarily storing (i) data for which operations are to be performed by the operation unit 1112, (ii) result data obtained by performing the operations and (iii) an address where data for performing of the operations are stored. The operation unit 1112 is a part which performs operations in the processor 1100. The operation unit 1112 performs arithmetical operations or logical operations in response to signals from the control unit 1113. The operation unit 1112 may include at least one arithmetic logic unit (ALU). The control unit 1113 receives signals from the memory unit 1111, the operation unit 1112, and an external device of the processor 1100, performs extraction, decoding, controlling upon input and output of commands, and executes processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122, and a tertiary storage section 1123. In general, the cache memory unit 1120 includes the primary and secondary storage sections 1121 and 1122, and may include the tertiary storage section 1123 in order to properly cope with the situation where high storage capacity is required. When appropriate, the cache memory unit 1120 may include an increased number of storage sections. That is to say, the number of storage sections which are included in the cache memory unit 1120 may be changed according to a design. The speeds at which the primary, secondary, and tertiary storage sections 1121, 1122 and 1123 store and discriminate data may be the same or different. In the case where the speeds of the respective storage sections 1121, 1122 and 1123 are different, the speed of the primary storage section 1121 may be set to be fastest. At least one storage section of the primary storage section 1121, the secondary storage section 1122, and the tertiary storage section 1123 of the cache memory unit 1120 may include one of the above-described semiconductor devices in accordance with the embodiments. The cache memory unit 1120 including the semiconductor device in accordance with the aforementioned embodiment may include a plurality of first conductive lines extending in a first direction, a plurality of second conductive lines extending in a second direction crossing with the first direction, and a plurality of resistance variable lines interposed between the first and second conductive lines and extending in a third direction crossing the first and second directions. Through this, a fabrication process of the cache memory unit 1120 may become simplified and the reliability of the cache memory unit 1120 may be improved. As a consequence, a fabrication process of the processor 1100 may become simplified and the reliability of the processor 1100 may be improved. Although it was shown in FIG. 9 that all the primary, secondary, and tertiary storage sections 1121, 1122 and 1123 are configured inside the cache memory unit 1120, the embodiments are not limited thereto. For example, it is to be noted that all the primary, secondary, and tertiary storage sections 1121, 1122 and 1123 of the cache memory unit 1120 may be configured outside the core unit 1110 and may compensate for a difference in data processing speed between the core unit 1110 and the external device. For another example, the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed.

The bus interface 1130 is a part which connects the core unit 1110 and the cache memory unit 1120 and allows data to be efficiently transmitted.

The processor 1100 according to the present embodiment may include a plurality of core units 1110, and the plurality of core units 1110 may share the same cache memory unit 1120. The plurality of core units 1110 and the cache memory unit 1120 may be connected through the bus interface 1130. The plurality of core units 1110 may be configured in substantially the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be faster than the processing speeds of the secondary and tertiary storage section 1122 and 1123.

The processor 1100 according to the present embodiment may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device. Besides, the processor 1100 may include a plurality of modules. In this case, the plurality of modules which are added may exchange data with the core units 1110, the cache memory unit 1120, and other units, through the bus interface 1130.

The embedded memory unit 1140 may include not only a volatile memory but also a nonvolatile memory. The volatile memory may include a dynamic random access memory (DRAM), a mobile DRAM, a static random access memory (SRAM), and so on. The nonvolatile memory may include a read only memory (ROM), a NOR flash memory, a NAND flash memory, a phase change random access memory (PRAM), a resistive random access memory (RRAM), a spin transfer torque random access memory (STTRAM), a magnetic random access memory (MRAM), and so on.

The communication module unit 1150 may include both a module capable of being connected with a wired network and a module capable of being connected with a wireless network. The wired network module may include a local area network (LAN), a universal serial bus (USB), an Ethernet, power line communication (PLC), and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), and so on.

The memory control unit 1160 is to administrate data transmitted between the processor 1100 and an external storage device operating according to a different communication standard. The memory control unit 1160 may include various memory controllers, for example, controllers for controlling IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 processes the data processed in the processor 1100 or the data inputted from the external input device and output the processed data to the external interface device to be transmitted in the forms of image, voice and others, and may include a graphic processing unit (GPU), a digital signal processor (DSP), a high definition audio (HD audio), a high definition multimedia interface (HDMI) controller, and so on.

FIG. 10 is a configuration diagram of a system in accordance with an embodiment.

Referring to FIG. 10, a system 1200 as an apparatus for processing data may perform input, processing, output, communication, storage, etc. to conduct a series of manipulations on data. The system 1200 may include a processor 1210, a main memory device 1220, an auxiliary memory device 1230, and an interface device 1240. The system 1200 of the present embodiment may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 is an essential component of the system 1200, and controls decoding of inputted commands and processing such as operation, comparison, etc. for the data stored in the system 1200, and may be constituted by a microprocessor unit (MPU), a central processing unit (CPU), a single/multi-core processor, a graphic processing unit (GPU), an application processor (AP), a digital signal processor (DSP), and so on.

The main memory device 1220 is a memory which can call and execute programs or data from the auxiliary memory device 1230 when programs are executed and can conserve memorized contents even when power supply is cut off. The main memory device 1220 may include one of the above-described semiconductor devices in accordance with the embodiments of. The main memory device 1220 including the semiconductor device in accordance with the aforementioned embodiment may include a plurality of first conductive lines extending in a first direction, a plurality of second conductive lines extending in a second direction crossing with the first direction, and a plurality of resistance variable lines interposed between the first and second conductive lines and extending in a third direction crossing with the first and second directions. Through this, a fabrication process of the main memory device 1220 may become simplified and the reliability of the main memory device 1220 may be improved. As a consequence, a fabrication process of the system 1200 may become simplified and the reliability of the system 1200 may be improved. Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the embodiments, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one of the above-described semiconductor devices in accordance with the embodiments. The auxiliary memory device 1230 including the semiconductor device in accordance with the aforementioned embodiment may include a plurality of first conductive lines extending in a first direction, a plurality of second conductive lines extending in a second direction crossing with the first direction, and a plurality of resistance variable lines interposed between the first and second conductive lines and extending in a third direction crossing with the first and second directions. Through this, a fabrication process of the auxiliary memory device 1230 may become simplified and the reliability of the auxiliary memory device 1230 may be improved. As a consequence, a fabrication process of the system 1200 may become simplified and the reliability of the system 1200 may be improved. Also, the auxiliary memory device 1230 may further include a data storage system (see the reference numeral 1300 of FIG. 11) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the embodiments, but may include data storage systems (see the reference numeral 1300 of FIG. 11) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present embodiment and an external device. The interface device 1240 may be a keypad, a keyboard, a mouse, a speaker, a mike, a display, various human interface devices (HIDs), and a communication device. The communication device may include both a module capable of being connected with a wired network and a module capable of being connected with a wireless network. The wired network module may include a local area network (LAN), a universal serial bus (USB), an Ethernet, power line communication (PLC), and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), and so on.

FIG. 11 is a configuration diagram of a data storage system in accordance with an embodiment.

Referring to FIG. 11, a data storage system 1300 may include a storage device 1310 which has a nonvolatile characteristic as a component for storing data, a controller 1320 which controls the storage device 1310, and an interface 1330 for connection with an external device. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The controller 1320 may control exchange of data between the storage device 1310 and the interface 1330. To this end, the controller 1320 may include a processor 1321 for performing an operation for and processing commands inputted through the interface 1330 from an outside of the data storage system 1300.

The interface 1330 is to perform exchange of commands and data between the data storage system 1300 and the external device. In the case where the data storage system 1300 is a card type, the interface 1330 may be an interface which is compatible with a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. In the case where the data storage system 1300 is a disk type, the interface 1330 may be an interface which is compatible with IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on.

The data storage system 1300 according to the present embodiment may further include a temporary storage device 1340 for efficiently transferring data between the interface 1330 and the storage device 1310 according to diversification and high performance of an interface with an external device, a controller and a system. The storage device 1310 and the temporary storage device 1340 for temporarily storing data may include one of the above-described semiconductor devices in accordance with the embodiments. The storage device 1310 or the temporary storage device 1340 including the semiconductor device in accordance with the aforementioned embodiment may include a plurality of first conductive lines extending in a first direction, a plurality of second conductive lines extending in a second direction crossing with the first direction, and a plurality of resistance variable lines interposed between the first and second conductive lines and extending in a third direction crossing with the first and second directions. Through this, a fabrication process of the storage device 1310 or the temporary storage device 1340 may become simplified and the reliability of the storage device 1310 or the temporary storage device 1340 may be improved. As a consequence, a fabrication process of the data storage system 1300 may become simplified and the reliability of the data storage system 1300 may be improved.

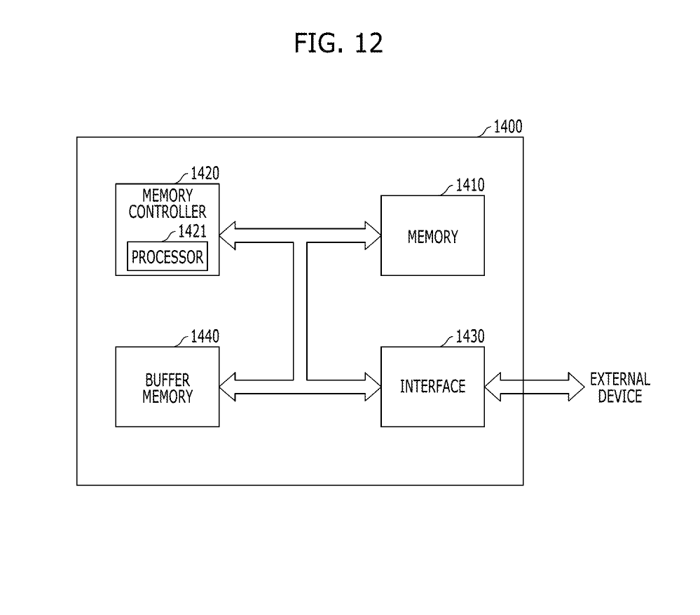

FIG. 12 is a configuration diagram of a memory system in accordance with an embodiment.

Referring to FIG. 12, a memory system 1400 may include a memory 1410 which has a nonvolatile characteristic as a component for storing data, a memory controller 1420 which controls the memory 1410, and an interface 1430 for connection with an external device. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one of the above-described semiconductor devices in accordance with the embodiments. The memory 1410 including the semiconductor device in accordance with the aforementioned embodiment may include a plurality of first conductive lines extending in a first direction, a plurality of second conductive lines extending in a second direction crossing with the first direction, and a plurality of resistance variable lines interposed between the first and second conductive lines and extending in a third direction crossing with the first and second directions. Through this, a fabrication process of the memory 1410 may become simplified and the reliability of the memory 1410 may be improved. As a consequence, a fabrication process of the memory system 1400 may become simplified and the reliability of the memory system 1400 may be improved. Also, the memory 1410 according to the present embodiment may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory system 1400 according to the present embodiment may further include a buffer memory 1440 for efficiently transferring data between the interface 1430 and the memory 1410 according to diversification and high performance of an interface with an external device, a memory controller and a memory system. The buffer memory 1440 for temporarily storing data may include one of the above-described semiconductor devices in accordance with the embodiments.

The buffer memory 1440 including the semiconductor device in accordance with the aforementioned embodiment may include a plurality of first conductive lines extending in a first direction, a plurality of second conductive lines extending in a second direction crossing with the first direction, and a plurality of resistance variable lines interposed between the first and second conductive lines and extending in a third direction crossing with the first and second directions. Through this, a fabrication process of the buffer memory 1440 may become simplified and the reliability of the buffer memory 1440 may be improved. As a consequence, a fabrication process of the memory system 1400 may become simplified and the reliability of the memory system 1400 may be improved.

Moreover, the buffer memory 1440 according to the present embodiment may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Unlike this, the buffer memory 1440 may not include the semiconductor devices according to the embodiments, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

As is apparent from the above descriptions, in the semiconductor device and the method for fabricating the same in accordance with the embodiments, processing is simplified, and interference between neighboring cells may be reduced.

Although various embodiments have been described for illustrative purposes, it will be apparent to those skilled in the art that various changes and modifications may be made without departing from the spirit and scope of the invention as defined in the following claims.

What is claimed is:

1. A semiconductor device comprising:
a plurality of first conductive lines extending in a first direction;
a plurality of second conductive lines extending in a second direction crossing the first direction; and
a plurality of resistance variable lines interposed between the first and the second conductive lines and extending in a third direction crossing the first and the second directions.

2. The semiconductor device according to claim 1, wherein unit memory cells are respectively formed at regions where the first conductive lines, the second conductive lines, and the resistance variable lines overlap with one another.

3. The semiconductor device according to claim 1, the semiconductor device further comprising:
conductive patterns interposed between the resistance variable lines and the second conductive lines, the conductive patterns respectively formed at regions where the second conductive lines and the resistance variable lines overlap with each other.

4. The semiconductor device according to claim 3, wherein the conductive patterns comprise metal and/or metal nitride.

5. The semiconductor device according to claim 1,
wherein a first angle formed by the first direction and the second direction is approximately a right angle, and
wherein a second angle formed by the third direction with respect to the first direction, and a third angle formed by the third direction with respect to the second direction are respectively between 0° and 90°, excluding 0°.

6. The semiconductor device according to claim 1,
wherein a first angle formed by the first direction and the third direction is approximately a right angle, and
wherein a second angle formed by the second direction with respect to the first direction, and a third angle formed by the second direction with respect to the third direction are respectively between 0° and 90°, excluding 0°.

7. The semiconductor device according to claim 1, wherein the semiconductor device includes a resistive random access memory, a phase change random access memory, a ferroelectric random access memory or a magnetic random access memory.

8. A system comprising:
a processor configured to decode a command inputted from outside and control an operation for information according to a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between (i) at least one of the processor, the auxiliary memory device and the main memory device and (ii) the outside,
wherein at least one of the auxiliary memory device and the main memory device comprises:
a plurality of first conductive lines extending in a first direction;
a plurality of second conductive lines extending in a second direction crossing the first direction; and
a plurality of resistance variable lines interposed between the first and the second conductive lines and extending in a third direction crossing the first and the second directions.

9. The system according to claim 8, wherein unit memory cells are respectively formed at regions where the first conductive lines, the second conductive lines, and the resistance variable lines overlap with one another.

10. The system according to claim 8, the at least one of the auxiliary memory device and the main memory device further comprising:
conductive patterns interposed between the resistance variable lines and the second conductive lines, the conductive patterns respectively formed at regions where the second conductive lines and the resistance variable lines overlap with each other.

11. The system according to claim 10, wherein the conductive patterns comprise metal and/or metal nitride.

12. The system according to claim 8,
wherein a first angle formed by the first direction and the second direction is approximately a right angle, and
wherein a second angle formed by the third direction with respect to the first direction, and a third angle formed by the third direction with respect to the second direction are respectively between 0° and 90°, excluding 0°.

13. The system according to claim 8,
wherein a first angle formed by the first direction and the third direction is approximately a right angle, and
wherein a second angle formed by the second direction with respect to the first direction, and a third angle formed by the second direction with respect to the third direction are respectively between 0° and 90°, excluding 0°.

14. The system according to claim 8, wherein the at least one of the auxiliary memory device and the main memory device includes a resistive random access memory, a phase change random access memory, a ferroelectric random access memory or a magnetic random access memory.

15. A data storage system comprising:
a storage device configured to store data and preserve stored data regardless of power supply;
a controller configured to control input and output of data to and from the storage device in response to an external command received from outside;
a temporary storage device configured to temporarily store data exchanged between the storage device and the outside; and
an interface configured to perform communication between (i) at least one of the storage device, the controller, and the temporary storage device and (ii) the outside,
wherein at least one of the storage device and the temporary storage device comprises:
a plurality of first conductive lines extending in a first direction;
a plurality of second conductive lines extending in a second direction crossing the first direction; and
a plurality of resistance variable lines interposed between the first and the second conductive lines and extending in a third direction crossing the first and the second directions.

16. The data storage system according to claim 15, wherein unit memory cells are respectively formed at regions where the first conductive lines, the second conductive lines, and the resistance variable lines overlap with one another.

17. The data storage system according to claim 15, the at least one of the storage device and the temporary storage device further comprising:
conductive patterns interposed between the resistance variable lines and the second conductive lines, the conductive patterns respectively formed at regions where the second conductive lines and the resistance variable lines overlap with each other.

18. The data storage system according to claim 17, wherein the conductive patterns comprise metal and/or metal nitride.

19. The data storage system according to claim 15,
wherein a first angle formed by the first direction and the second direction is approximately a right angle, and
wherein a second angle formed by the third direction with respect to the first direction, and a third angle formed by the third direction with respect to the second direction are respectively between 0° and 90°, excluding 0°.

20. The data storage system according to claim 15, wherein the at least one of the storage device and the temporary storage device includes a resistive random access memory, a phase change random access memory, a ferroelectric random access memory or a magnetic random access memory.
